(19) United States
(12) Patent Application Publication
(10) Pub. No.: US 2009/0161300 A1
(43) Pub. Date: Jun. 25, 2009

(54) CIRCUIT BOARD WITH HEAT DISSIPATION FUNCTION

(76) Inventor: Yeh-Hsun CHOU, TAOYUAN COUNTY (TW)

Correspondence Address: BROWDY AND NEIMARK, P.L.L.C.;624 NINTH STREET, NW, SUITE 300, WASHINGTON, DC, 20001-5303, US

(21) Appl. No.: 12/233,801

(22) Filed: Sep. 19, 2008

(30) Foreign Application Priority Data
Dec. 21, 2007 (TW) 96221877

(51) Int. Cl. H05K 7/20

(52) U.S. Cl. 361/619; 361/689

(57) ABSTRACT

A circuit board for direct dissipation of heat energy from the installed electronic devices to facilitate the fabrication of a light-weight design of electronic product is disclosed to include a heat sink, a first insulating layer and a circuit layout. The heat sink has a working fluid contained in an enclosed chamber inside an envelope and a wick layer fixedly attached to the inner surface of the enclosed chamber for absorbing the working fluid. The first insulating layer is covered on the envelope of the heat sink. The circuit layout is arranged on a surface of the first insulating layer opposite to the envelope of the heat sink.

### BACKGROUND OF THE INVENTION

1. Field of the Invention

The present invention relates to print circuit boards and more particularly, to a circuit board with heat dissipation function that rapidly dissipates heat from the electronic devices installed on the circuit board.

2. Description of the Related Art

Regular printed circuit boards commonly comprise an insulating substrate made from bakelite or glass fiber-reinforced resin, and a circuit layout arranged on the surface of the insulating substrate. Subject to different requirements, CPU, LEDs and/or other electronic devices may be installed in the circuit layout of a printed circuit board. Waste heat from an electronic device on a circuit board may be transferred to another place through a heat pipe that has a heat receiving end closely attached to the electronic device and a heat dissipating end connected with a plurality of fins. Through the heat pipe, waste heat is transferred from the electronic device to the fins for quick dissipation into the outside open air.

The above structure has heat dissipation function. However, for heat dissipation from multiple electronic devices at a circuit board, size and/or number of the heat pipes and the fins are relatively large. This arrangement is not in favor of the fabrication of light-weight designs of electronic products.

Therefore, it is desirable to provide a circuit board design that eliminates the aforesaid problem.

### SUMMARY OF THE INVENTION

The present invention has been accomplished under the circumstances in view. It is the main object of the present invention to provide a circuit board with heat dissipation function, which directly dissipates waste heat from the electronic devices installed thereon.

It is another object of the present invention to provide a circuit board with heat dissipation function, which facilitates the fabrication of light-weight designs of electronic products.

To achieve these and other objects of the present invention, the circuit board is comprised of a heat sink, a first insulating layer and a circuit layout. The heat sink comprises an envelope, an enclosed chamber defined inside the envelope, a working fluid contained in the enclosed chamber, and a wick layer fixedly attached to the inner surface of the enclosed chamber for absorbing the working fluid. The first insulating layer is covered on at least one part of the envelope. The circuit layout is arranged on a surface of the first insulating layer opposite to the envelope.

### BRIEF DESCRIPTION OF THE DRAWING

FIG. 1 is a perspective view of a circuit board in accordance with a preferred embodiment of the present invention.

FIG. 2 is a sectional view of the circuit board mounted with electronic devices in accordance with the preferred embodiment of the present invention.

FIG. 3 is a schematic sectional view showing one application example of the circuit board according to the present invention.

FIG. 4 is a schematic sectional view showing another application example of the circuit board according to the present invention.

### DETAILED DESCRIPTION OF THE INVENTION

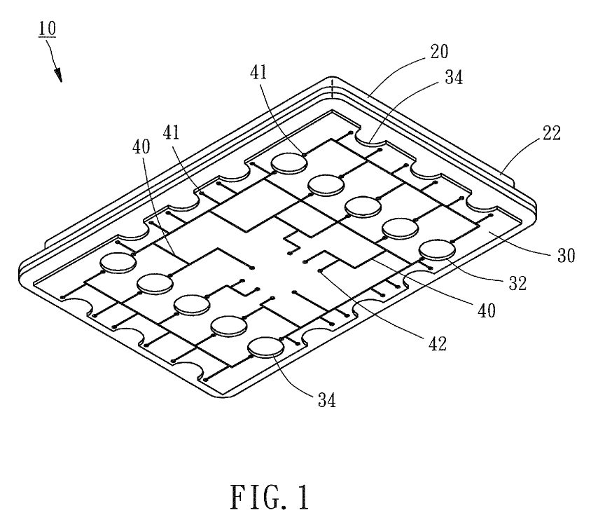

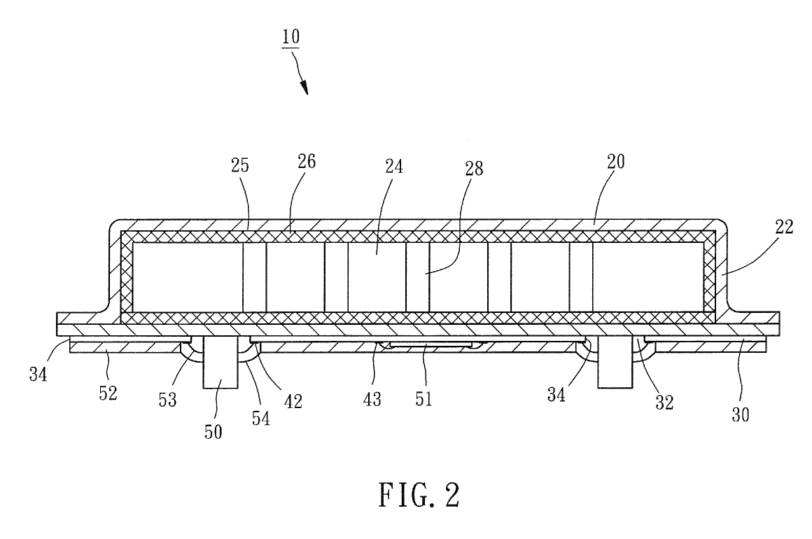

Referring to FIGS. 1 and 2, a circuit board 10 with heat dissipation function in accordance with the present invention is shown comprising a heat sink 20, a first insulating layer 30 and a circuit layout 40. The circuit board 10 has installed thereon multiple electronic devices 50 and 51 and covered thereon a second insulating layer 52 and multiple encapsulations 54 to package the electronic devices 50 and 51.

The heat sink 20 comprises an envelope 22 made of copper, aluminum or any other high thermal conducting metal material and defining therein an enclosed chamber 24, a working fluid, for example, water (not shown), contained in the enclosed chamber 24, a wick layer 26 made of sintered copper powder and/or copper net and fixedly attached to the inner surface 25 of the enclosed chamber 24 for absorbing the working fluid, and a plurality of metal pillars 28 respectively stopped with the top and bottom ends thereof against the inner surface 25 of the enclosed chamber 24 for supporting the envelope 22 and transferring heat energy. When the bottom side of the envelope 22 is being heated, the working fluid at the bottom side of the wick layer 26 absorbs heat and is changed from liquid to steam. When steam reaches the top side of the envelope 22, it releases heat and condenses into liquid that is then delivered by the wick layer 26 back to the bottom side of the envelope 22 for further circulation. By means of the aforesaid circulation, the heat sink 20 rapidly dissipates heat generated by the bottom heat source.

The first insulating layer 30 is covered on the outer surface of the bottom wall of the envelope 22 of the heat sink 20. The first insulating layer 30 can be prepared from, but not limited to, bakelite or glass fiber reinforced resin. The first insulating layer 30 is provided with a plurality of openings 32. The peripheries of the openings 32 together with the periphery of the first insulating layer 30 forming a plurality of edge 34.

The circuit layout 40 is arranged on the surface of the first insulating layer 30. The circuit layout 40 has a plurality of first contacts 42 respectively disposed adjacent to the edges 34 of the first insulating layer 30 for electrically connecting a plurality of first electronic devices 50, such as LEDs. The first electronic devices 50 are respectively inserted through the openings 32 and bonded to the envelope 22 of the heat sink 20. The circuit layout 40 further comprises a plurality of second contacts 43 disposed remote from the edges 34 of the first insulating layer 30 for electrically connecting a second electronic device 51, for example, CPU.

The second insulating layer 52 is covered on the first insulating layer 30 and the circuit layout 40 to package the second electronic device 51. But the first contacts 42 are not covered by the second insulating layer 52 and exposed to the outside. After bonding of the first electronic devices 50 to the envelope 22 of the heat sink 20 and connection of the first electronic devices 50 to the first contacts 42 with two conducting wires 53, encapsulations 54 are used to package the first contacts 42 and the conducting wires 53, as shown in FIG. 2.

Thus, heat energy generated during operation of the first electronic devices 50 is directly transferred to the heat sink 20 for quick dissipation, and heat energy generated during operation of the second electronic device 51 is transferred through the first insulating layer 30 to the heat sink 20 for further dissipation. When compared with conventional designs through heat pipes and fins to dissipate waste heat, the heat transfer path of the present invention is short and has the advantages of higher heat dissipation efficiency and simple structure, facilitating light-weight designs of electronic products and suitable for use in products for heat dissipation from big area or numerous electronic devices, such as monitors, street lights, traffic lights, vehicle lights, etc.

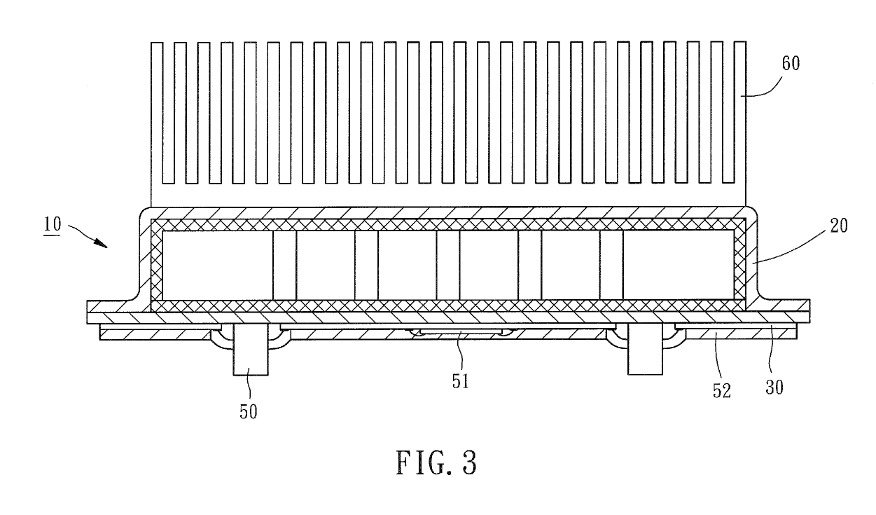

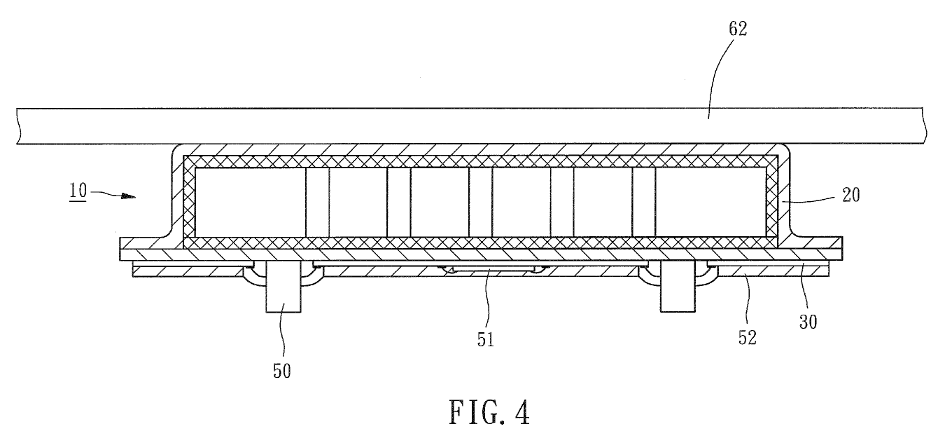

In actual practice, dissipation fins 60 may be provided at the top side of the heat sink 20, as shown in FIG. 3, or, the heat sink 20 can be directly stopped against a lamp holder 62 or device case, as shown in FIG. 4, to increase heat dissipation area, thereby improving heat dissipation efficiency. A cooling fan may be installed at the top side of the heat sink 20 to accelerate heat dissipation.

Based on the spirit of the present invention, the structure and shape of the circuit board 10 may be variously embodied. For example, the circuit board 10 can be made having a planar, curved or irregular shape; the first insulating layer 30 can be covered on only a specific part of the envelope 22; the first insulating layer 30 can be made without the aforesaid openings 32; there is no limit to the number of the contacts 42 and 43 of the circuit layout 40.

Although a particular embodiment of the invention has been described in detail for purposes of illustration, various modifications and enhancements may be made without departing from the spirit and scope of the invention. Accordingly, the invention is not to be limited except as by the appended claims.

What is claimed is:

1. A circuit board, comprising:
a heat sink having an envelope, an enclosed chamber defined inside said envelope, a working fluid contained in said enclosed chamber, and a wick layer attached to an inner surface of said enclosed chamber for absorbing said working fluid;
a first insulating layer covered on at least one part of said envelope; and
a circuit layout arranged on a surface of said first insulating layer opposite to said envelope.

2. The circuit board as claimed in claim 1, wherein said circuit layout has at least one first contact disposed adjacent to an edge of said first insulating layer.

3. The circuit board as claimed in claim 1, wherein said first insulating layer is provided with at least one opening having a periphery forming a part of an edge of said first insulating layer.

4. The circuit board as claimed in claim 2, further comprising at least one first electronic device bonded to said envelope of said heat sink and electrically connected with said at least one first contact.

5. The circuit board as claimed in claim 1, further comprising a second insulating layer covered on said first insulating layer and said circuit layout.

6. The circuit board as claimed in claim 1, wherein said circuit layout further comprises at least one second contact, which is disposed remote from an edge of said first insulating layer, for electrically connecting with at least one second electronic device.

7. The circuit board as claimed in claim 1, wherein said heat sink further comprises a plurality of pillars respectively stopped with top and bottom ends thereof against the inner surface of said enclosed chamber.
